(19) United States
(12) Patent Application Publication
(10) Pub. No.: US 2026/0247682 A1
(43) Pub. Date: Aug. 20, 2026

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Hiroki MIYAKE, Nisshin-shi (JP); Hirofumi KIDA, Nisshin-shi (JP)

(21) Appl. No.: 19/448,847

(22) Filed: Jan. 14, 2026

(30) Foreign Application Priority Data
Feb. 14, 2025 (JP) 2025-022554

(51) Int. Cl. H10D 64/23; H10D 10/60

(52) U.S. Cl. CPC H10D 64/231; H10D 10/60

(57) ABSTRACT

A semiconductor device includes a collector layer, a base layer disposed above the collector layer, an emitter layer disposed above the base layer and having a width narrower than a width of the base layer, a collector electrode electrically connected to the collector layer, an emitter electrode electrically connected to the emitter layer, a base electrode electrically connected to the base layer, and a surface recombination prevention layer disposed between the emitter layer and the base layer, and having a structure different from the base layer and emitter layer. The surface recombination prevention layer is disposed so as to cover, on one surface of the base layer that faces the emitter layer, a region located between an emitter-layer facing portion that faces the emitter layer and a base-electrode facing portion that faces the base electrode.

### CROSS REFERENCE TO RELATED APPLICATION

The present application claims the benefit of priority from Japanese Patent Application No. 2025-022554 filed on February 14, 2025. The entire disclosure of the above application is incorporated herein by reference.

### TECHNICAL FIELD

The present disclosure relates to a semiconductor device.

### BACKGROUND

Conventionally, a semiconductor device including a bipolar transistor in which a collector layer, a base layer, and an emitter layer are sequentially stacked has been proposed.

### SUMMARY

A semiconductor device according to one aspect of the present disclosure includes: a collector layer of a first conductivity type; a base layer of a second conductivity type disposed above the collector layer; an emitter layer of the first conductivity type disposed above the base layer and having a mesa structure such that, in a direction intersecting a stacking direction of the collector layer and the base layer, a width of the emitter layer is narrower than a width of the base layer, a collector electrode electrically connected to the collector layer; an emitter electrode electrically connected to the emitter layer; and a base electrode electrically connected to the base layer. The semiconductor device may further include a surface recombination prevention layer disposed between the emitter layer and the base layer and having a structure different from those of the base layer and the emitter layer. The base layer may have one surface that faces the emitter layer. The one surface may have an emitter-layer facing portion that faces the emitter layer in the stacking direction, a base-electrode facing portion that faces the base electrode in the stacking direction, and a region located between the emitter-layer facing portion and the base-electrode facing portion. The surface recombination prevention layer may be disposed to cover the region of the one surface.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional view of a semiconductor device according to a first embodiment;

FIG. 2 is a diagram for explaining the operating state of the semiconductor device according to the first embodiment;

FIG. 3 is a cross-sectional view of a semiconductor device according to a second embodiment; and

FIG. 4 is a cross-sectional view of a semiconductor device according to a third embodiment.

### DETAILED DESCRIPTION

Next, relevant technology is described to facilitate understanding of the following embodiments. A semiconductor device includes a bipolar transistor in which a collector layer, a base layer, and an emitter layer are sequentially stacked. Specifically, in this semiconductor device, a mesa structure is adopted in which the emitter layer is made narrower than a width of the base layer, in order to reduce parasitic capacitance and the like. In other words, the base layer of this semiconductor device has a shape that includes a portion protruding from the emitter layer in the stacking direction of the base layer and the emitter layer. Furthermore, in this semiconductor device, the emitter layer has a ledge structure in order to suppress surface recombination at the portion protruding from the emitter layer on one surface of the base layer that faces the emitter layer.

However, if the ledge structure is formed in the emitter layer, both the ledge structure and the mesa structure are formed in the emitter layer, which may complicate the manufacturing process.

A semiconductor device according to a first aspect of the present disclosure includes: a collector layer of a first conductivity type; a base layer of a second conductivity type disposed above the collector layer; an emitter layer of the first conductivity type disposed above the base layer and having a mesa structure such that, in a direction intersecting a stacking direction of the collector layer and the base layer, a width of the emitter layer is narrower than a width of the base layer, a collector electrode electrically connected to the collector layer; an emitter electrode electrically connected to the emitter layer; a base electrode electrically connected to the base layer; and a surface recombination prevention layer disposed between the emitter layer and the base layer and having a structure different from those of the base layer and the emitter layer. The base layer has one surface that faces the emitter layer. The one surface has an emitter-layer facing portion that faces the emitter layer in the stacking direction, a base-electrode facing portion that faces the base electrode in the stacking direction, and a region located between the emitter-layer facing portion and the base-electrode facing portion. The surface recombination prevention layer is disposed to cover the region of the one surface.

In the semiconductor device according to the first aspect, on the one surface of the base layer that faces the emitter layer, the region located between the base-electrode facing portion and the emitter-layer facing portion is covered with the surface recombination prevention layer. As a result, surface recombination on the one surface of the base layer that faces the emitter layer can be suppressed, thereby suppressing a decrease in current gain. In addition, the surface recombination prevention layer has a different structure from the emitter layer. Therefore, the designs of the emitter layer and the surface recombination prevention layer can be separated, which allows for suppression of increased complexity in the manufacturing process.

A semiconductor device according to a second aspect of the present disclosure includes: a collector layer of a first conductivity type; a base layer of a second conductivity type disposed above the collector layer; an emitter layer of the first conductivity type disposed above the base layer and having a mesa structure such that, in a direction intersecting a stacking direction of the collector layer and the base layer, a width of the emitter layer is narrower than a width of the base layer; a collector electrode electrically connected to the collector layer; an emitter electrode electrically connected to the emitter layer; and a surface recombination prevention layer disposed between the emitter layer and the base layer and having a structure different from those of the base layer and the emitter layer. The base layer has one surface that faces the emitter layer. The one surface has a region capable of serving as a current path. The surface recombination prevention layer is disposed so as to cover the region of the one surface.

In the semiconductor device according to the second aspect, on the one surface of the base layer that faces the emitter layer, the region capable of serving as the current path is covered with the surface recombination prevention layer. As a result, surface recombination on the one surface of the base layer that faces the emitter layer can be suppressed, thereby suppressing a decrease in current gain. In addition, the surface recombination prevention layer has a different structure from the emitter layer. Therefore, the designs of the emitter layer and the surface recombination prevention layer can be separated, which allows for suppression of increased complexity in the manufacturing process.

The following describes embodiments of the present disclosure with reference to the drawings. In the following embodiments, the same or equivalent parts are denoted by the same reference numerals for description.

### First embodiment

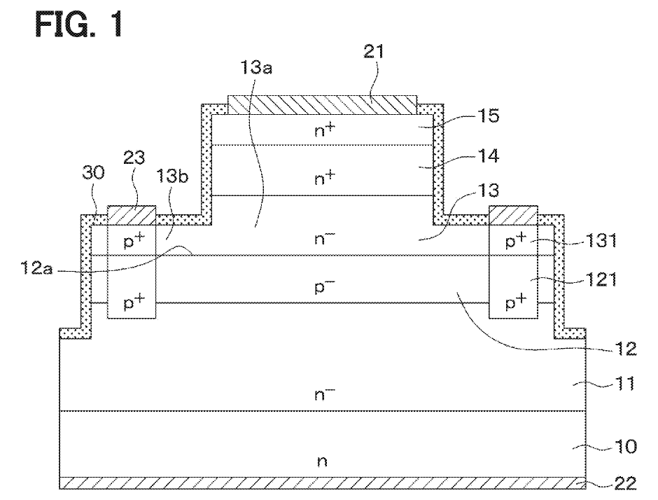

A first embodiment will be described with reference to the drawings. As shown in FIG. 1, a semiconductor device includes a support substrate 10. In the present embodiment, the support substrate 10 is composed of gallium nitride (GaN), and is an n-type substrate with an n-type carrier concentration higher than that of the collector layer 11, which will be described later.

On the support substrate 10, a collector layer 11 composed of GaN is disposed. The collector layer 11 is, for example, an n⁻-type layer with a carrier concentration of 1×10¹⁶ cm⁻³, in which impurities such as silicon are doped, and has a thickness of 6 μm. Furthermore, in the present embodiment, the collector layer 11 has a recessed portion at an outer edge of a surface that faces the base layer 12, which will be described later.

On the collector layer 11, the base layer 12 composed of GaN is disposed. The base layer 12 is, for example, a p⁻-type layer in which impurities such as magnesium (Mg) are doped, and has a thickness of 100 nm. If the p-type carrier concentration in the base layer 12 is too high, when the semiconductor device is in the ON state as described later, the lifetime of electrons supplied from the emitter layer 14 tends to become shorter. Therefore, it is preferable that a peak concentration at a portion in the base layer 12 where the p-type carrier concentration is highest is set to 2×10¹⁹ cm⁻³ or less. In addition, if the p-type carrier concentration in the base layer 12 is too low, there is a possibility that the required breakdown voltage may not be satisfied. Therefore, it is preferable that the peak concentration at the portion in the base layer 12 where the p-type carrier concentration is highest is set to 1×10¹⁷ cm⁻³ or more. In other words, it is preferable that the peak concentration at the portion in the base layer 12 where the p-type carrier concentration is highest is set to be between 1×10¹⁷ cm⁻³ and 2×10¹⁹ cm⁻³, inclusive.

In the base layer 12 of the present embodiment, a first base contact layer 121 is formed at a position different from a position facing the emitter layer 14, which will be described later. The first base contact layer 121 of the present embodiment is formed so as to penetrate the base layer 12 in the thickness direction and reach the collector layer 11. However, the first base contact layer 121 may be formed so as to terminate within the base layer 12 and not reach the collector layer 11. In the present embodiment, the first base contact layer 121 has a higher p-type carrier concentration than the base layer 12. For example, impurities such as Mg are doped, and the p-type carrier concentration is set to 4×10¹⁹ cm⁻³.

On the base layer 12, a surface recombination prevention layer 13, which has a different structure from those of the base layer 12 and the emitter layer 14 (which will be described later) is disposed. In the present embodiment, the surface recombination prevention layer 13 is composed of aluminum gallium nitride (AlGaN) with an Al composition of approximately 15%. However, the ratio of each constituent can be appropriately modified. Furthermore, in the present embodiment, the surface recombination prevention layer 13 is, for example, doped with impurities such as silicon to be n⁻-type, and has a thickness of 100 nm. It should be noted that, as will be described in detail later, the surface recombination prevention layer 13 of the present embodiment is configured such that a portion serving as a second surface recombination prevention layer 13b is completely depleted. Therefore, if the carrier concentration is made too high, it becomes necessary to make the film thickness extremely thin in order to achieve complete depletion. Accordingly, it is preferable that the surface recombination prevention layer 13 has an n-type carrier concentration of 1×10¹⁷ cm⁻³ or less, and in the present embodiment, the n-type carrier concentration is set to 1×10¹⁶ cm⁻³. The specific structure and arrangement of the surface recombination prevention layer 13 will be described later, but the surface recombination prevention layer 13 is disposed on a region of one surface 12a of the base layer 12 that is capable of serving as a current path.

In addition, on the surface recombination prevention layer 13, a second base contact layer 131, which is connected to the first base contact layer 121, is disposed at a position different from the position facing the emitter layer 14 (which will be described later). Specifically, the second base contact layer 131 is arranged so as to penetrate through the surface recombination prevention layer 13 in the thickness direction. Additionally, in the present embodiment, the second base contact layer 131, like the first base contact layer 121, is doped with an impurity such as Mg, for example, so that the p-type carrier concentration is set to 4×10¹⁹ cm⁻³.

It should be noted that, in the present embodiment, the first base contact layer 121 and the second base contact layer 131 are formed by ion implantation of a p-type impurity such as Mg. However, the methods for forming the first base contact layer 121 and the second base contact layer 131 may be appropriately modified. For example, the first base contact layer 121 and the second base contact layer 131 may be formed by forming trenches in the regions where the first base contact layer 121 and the second base contact layer 131 are to be formed, and then placing a buried epitaxial layers in these trenches.

On the surface recombination prevention layer 13, the emitter layer 14 composed of AlGaN, which is a material with a larger band gap than the base layer 12, is disposed. The emitter layer 14 is, for example, an n⁺-type layer in which impurities such as silicon are doped to provide an n-type carrier concentration of 7×10¹⁸ cm⁻³, and has a thickness of 50 nm.

On the emitter layer 14, an emitter contact layer 15 is disposed so as to be in ohmic connection with an emitter electrode 21, which will be described later. In the present embodiment, the emitter contact layer 15 is composed, for example, of GaN, is of n⁺-type with impurities such as silicon doped to provide an n-type carrier concentration of 7×10¹⁸ cm⁻³, and has a thickness of 50 nm.

In addition, the emitter layer 14 and the emitter contact layer 15 are formed in a mesa structure such that widths of the emitter layer 14 and the emitter contact layer 15 are narrower than a width of the base layer 12. Therefore, the base layer 12 has a portion facing the emitter layer 14 and a portion not facing the emitter layer 14. Here, the width refers to the length in the direction perpendicular to the stacking direction of the collector layer 11, the base layer 12, and the emitter layer 14. In FIG. 1, the width corresponds to the length in the left-right direction of the drawing. In addition, the stacking direction of the collector layer 11, the base layer 12, and the emitter layer 14 corresponds to the vertical direction in FIG. 1, and hereinafter, it is simply referred to as the stacking direction.

The emitter layer 14 and the emitter contact layer 15 are formed as follows. First, on the support substrate 10, constituent films forming the collector layer 11, the base layer 12, the surface recombination prevention layer 13, the emitter layer 14, and the emitter contact layer 15 are sequentially stacked in this order by epitaxial growth or the like. Thereafter, by appropriately placing a mask and performing dry etching on the constituent films forming the emitter layer 14 and the emitter contact layer 15, the emitter layer 14 and the emitter contact layer 15 having a mesa structure are formed. At this time, in the present embodiment, a portion of the surface recombination prevention layer 13 other than a portion facing the emitter layer 14 is partially removed by dry etching. Therefore, in the surface recombination prevention layer 13, the portion not facing the emitter layer 14 is thinner than the portion facing the emitter layer 14.

On the emitter contact layer 15, the emitter electrode 21 that is electrically connected to the emitter contact layer 15 is disposed. On the side of the support substrate 10 opposite to the collector layer 11, a collector electrode 22 electrically connected to the collector layer 11 is disposed. The emitter electrode 21 and the collector electrode 22 are, for example, formed by stacking titanium and aluminum.

On the second base contact layer 131, a base electrode 23 that is electrically connected to the base layer 12 is disposed. The base electrode 23 is electrically connected to the base layer 12 through the second base contact layer 131 and the first base contact layer 121. The base electrode 23 is composed of, for example, palladium (Pd) or the like.

In the semiconductor device of the present embodiment, in order to suppress leakage current, a protective film 30, composed of an oxide film or the like and having a thickness of approximately 50 nm, is disposed so as to cover outer surfaces of the emitter contact layer 15, the emitter layer 14, the surface recombination prevention layer 13, the base layer 12, the collector layer 11.

Here, the placement location and configuration of the surface recombination prevention layer 13 will be described in detail. The surface recombination prevention layer 13 is disposed on the one surface 12a of the base layer 12 that faces the emitter layer 14 (hereinafter also simply referred to as the one surface 12a of the base layer 12), so as to cover the region capable of serving as the current path. In the present embodiment, the surface recombination prevention layer 13 is arranged so as to cover, at least, a region of the one surface 12a of the base layer 12 located between a portion that faces the emitter layer 14 in the stacking direction (hereinafter, referred to as “emitter-layer facing portion”) and a portion where the first base contact layer 121 is formed. In other words, the surface recombination prevention layer 13 is arranged so as to cover, at least a region of one surface 12a of the base layer 12 located from the emitter-layer facing portion to a portion facing the base electrode 23 in the stacking direction (hereinafter, referred to as “base-electrode facing portion”).

Hereinafter, in the surface recombination prevention layer 13, a region between the emitter layer 14 and the base layer 12 will be referred to as a first surface recombination prevention layer 13a. Furthermore, hereinafter, in the surface recombination prevention layer 13, a region that is different from the first surface recombination prevention layer 13a and includes a region located between the second base contact layer 131 and the first surface recombination prevention layer 13a within the surface recombination prevention layer 13 will be referred to as a second surface recombination prevention layer 13b. In the present embodiment, the first surface recombination prevention layer 13a and the second surface recombination prevention layer 13b are each composed of AlGaN and have the same configuration. However, the first surface recombination prevention layer 13a and the second surface recombination prevention layer 13b may have different configurations.

In the present embodiment, by configuring the base layer 12 and the surface recombination prevention layer 13 as described above, a bandgap of the second surface recombination prevention layer 13b is made larger than a bandgap of the base layer 12. Furthermore, the carrier concentration and the thickness of the second surface recombination prevention layer 13b are adjusted so that, when the semiconductor device is in the ON state as described later, the second surface recombination prevention layer 13b is fully depleted.

The configuration of the semiconductor device according to the present embodiment has been described above. In the present embodiment, the n-type corresponds to a first conductivity type, and the p-type corresponds to a second conductivity type.

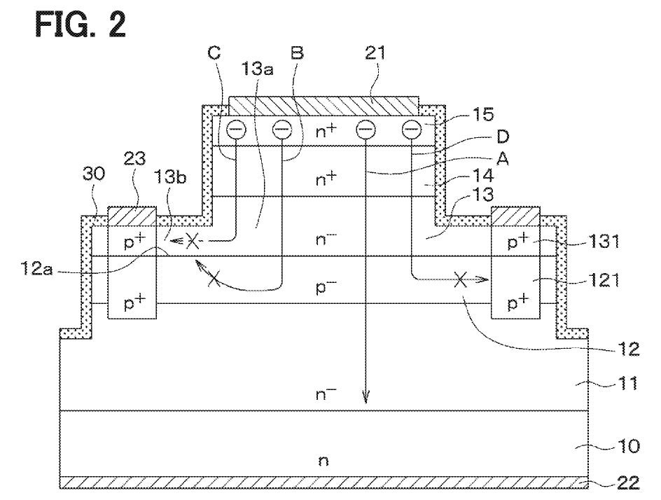

When a predetermined voltage is applied between the emitter electrode 21 and the base electrode 23 while a higher voltage is applied to the collector electrode 22 than to the emitter electrode 21, as shown by arrow A in FIG. 2, electrons flow from the emitter layer 14 through the base layer 12 to the collector layer 11, thereby turning the semiconductor device on. It should be noted that, in FIG. 2, electrons are indicated by the symbol “-”. At this time, in the present embodiment, the region of the one surface 12a of the base layer 12 capable of serving as the current path is covered with the surface recombination prevention layer 13. Specifically, the region of the one surface 12a of the base layer 12 from the emitter-layer facing portion to the first base contact layer 121 is covered with the surface recombination prevention layer 13. Therefore, it becomes more difficult for electrons to undergo surface recombination on the one surface 12a of the base layer 12, thereby suppressing a decrease in current gain due to electron loss.

In addition, in the present embodiment, the second surface recombination prevention layer 13b is configured to have a larger band gap than the base layer 12. Therefore, as indicated by arrow B, it is possible to suppress the electrons that have flowed from the emitter layer 14 to the base layer 12 from flowing back into the second surface recombination prevention layer 13b. Accordingly, it is possible to further suppress the decrease in current gain.

Furthermore, in the present embodiment, the second surface recombination prevention layer 13b is configured to be fully depleted when the semiconductor device is in the ON state. Therefore, as indicated by arrow C, electrons that have flowed from the emitter layer 14 to the surface recombination prevention layer 13 are suppressed from flowing from the first surface recombination prevention layer 13a to the second surface recombination prevention layer 13b and being discharged through the second base contact layer 131. Accordingly, it is possible to further suppress the decrease in current gain.

In the present embodiment, the first base contact layer 121 and the second base contact layer 131 have a higher p-type carrier concentration than the base layer 12. Therefore, for example, compared to a case where the p-type carrier concentration of the second base contact layer 131 is the same as that of the base layer 12, it is possible to reduce the contact resistance between the base electrode 23 and the second base contact layer 131. When moving within a p-type layer, electrons tend to move more easily from a side with a higher carrier concentration to a side with a lower carrier concentration. Accordingly, as indicated by arrow D, electrons that have flowed from the emitter layer 14 into the base layer 12 are less likely to enter the first base contact layer 121 from the base layer 12, and electrons are suppressed from being discharged through the first base contact layer 121. Furthermore, since the first base contact layer 121, which has a higher p-type carrier concentration than the base layer 12, is used to connect the base layer 12 to the base electrode 23, it is not necessary to make the p-type carrier concentration of the base layer 12 high. Therefore, for example, compared to a case where the p-type carrier concentration of the base layer 12 is the same as that of the first base contact layer 121, it is possible to suppress the shortening of the lifetime of electrons. As a result, it is possible to further suppress the decrease in current gain.

According to the present embodiment described above, in the one surface 12a of the base layer 12 that faces the emitter layer 14, the emitter-layer facing portion and the region located between the emitter-layer facing portion and the base-electrode facing portion are covered with the surface recombination prevention layer 13. In other words, on the one surface 12a of the base layer 12, the region capable of serving as the current path is covered with the surface recombination prevention layer 13. As a result, surface recombination on the one surface 12a of the base layer 12 that faces the emitter layer 14 can be suppressed, thereby suppressing the decrease in current gain. Furthermore, the surface recombination prevention layer 13 has a structure different from the emitter layer 14. Accordingly, the emitter layer 14 and the surface recombination prevention layer 13 can be designed independently, thereby preventing the manufacturing process from becoming complicated.

In the present embodiment, the first base contact layer 121 is formed in the base layer 12, and the second base contact layer 131 is formed in the surface recombination prevention layer 13. The base layer 12 is electrically connected to the base electrode 23 via the first base contact layer 121 and the second base contact layer 131. Therefore, it is possible to prevent the base layer 12 from being in a floating state.

In the present embodiment, the second surface recombination prevention layer 13b has a larger band gap than the base layer 12. Therefore, when the semiconductor device is in the ON state, it is possible to suppress electrons that have flowed from the emitter layer 14 to the base layer 12 from flowing back into the second surface recombination prevention layer 13b. Accordingly, it is possible to further suppress the decrease in current gain.

In the present embodiment, the second surface recombination prevention layer 13b is configured to be fully depleted when the semiconductor device is in the ON state. Therefore, electrons that have flowed from the emitter layer 14 to the surface recombination prevention layer 13 are prevented from flowing from the first surface recombination prevention layer 13a to the second surface recombination prevention layer 13b, and from being discharged through the second base contact layer 131. Accordingly, it is possible to further suppress the decrease in current gain.

In the present embodiment, the first base contact layer 121 and the second base contact layer 131 have a higher p-type carrier concentration than the base layer 12. Therefore, for example, compared to a case where the p-type carrier concentration of the second base contact layer 131 is the same as that of the base layer 12, it is possible to reduce the contact resistance between the base electrode 23 and the second base contact layer 131. In addition, electrons that have flowed from the emitter layer 14 into the base layer 12 are less likely to enter the first base contact layer 121 from the base layer 12, and thus electrons are suppressed from being discharged through the first base contact layer 121. Furthermore, since the first base contact layer 121, which has a higher p-type carrier concentration than the base layer 12, is used to connect the base layer 12 to the base electrode 23, it is not necessary to make the p-type carrier concentration of the base layer 12 high. Therefore, for example, compared to a case where the p-type carrier concentration of the base layer 12 is the same as that of the first base contact layer 121, it is possible to suppress the shortening of the lifetime of electrons. Accordingly, it is possible to further suppress the decrease in current gain.

In the present embodiment, the base layer 12 has a peak p-type carrier concentration of 2×10¹⁹ cm⁻³ or less. Therefore, it is possible to suppress the shortening of the lifetime of electrons supplied from the emitter layer 14 when the semiconductor device is in the ON state. Accordingly, it is possible to further suppress the decrease in current gain.

### Modification to the First Embodiment

Modifications to the first embodiment will be described below. In the first embodiment described above, the p-type carrier concentration of the second base contact layer 131 may be higher than the p-type carrier concentration of the first base contact layer 121. Accordingly, electrons are less likely to flow from the first base contact layer 121 to the second base contact layer 131, and thus electrons are further suppressed from being discharged through the base electrode 23.

### Second Embodiment

The following describes a second embodiment of the present disclosure. The present embodiment differs from the first embodiment in that an etching stopper layer is added. The other configurations of the present embodiment are similar to those of the first embodiment, and therefore a description of similar configurations is omitted.

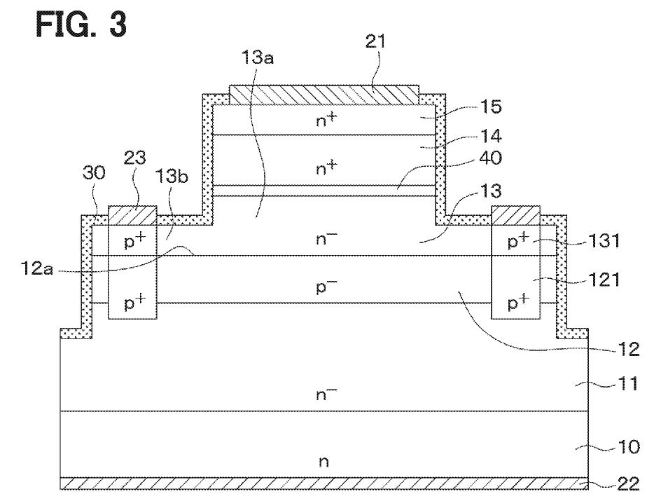

As shown in FIG. 3, in the semiconductor device of the present embodiment, an etching stopper layer 40 is disposed between the base layer 12 and the emitter layer 14. The etching stopper layer 40 is composed of a material different from the surface recombination prevention layer 13 and the emitter layer 14, and has a lower etching rate than the surface recombination prevention layer 13 and the emitter layer 14. In the present embodiment, the etching stopper layer 40 is disposed between the first surface recombination prevention layer 13a and the emitter layer 14, and is composed of, for example, aluminum (Al).

It should be noted that in FIG. 3, when forming the mesa structure by dry-etching the constituent film forming the emitter layer 14 and the constituent film forming the emitter contact layer 15, the etching stopper layer 40 disposed on the second surface recombination prevention layer 13b has been removed. However, although not specifically illustrated, the etching stopper layer 40 may also be disposed on the second surface recombination prevention layer 13b. If the etching stopper layer 40 is also disposed on the second surface recombination prevention layer 13b, the height of the portion of the etching stopper layer 40 disposed on the first surface recombination prevention layer 13a and the portion disposed on the second surface recombination prevention layer 13b will be the same. Furthermore, the etching stopper layer 40 may also be disposed, for example, inside the first surface recombination prevention layer 13a.

According to the present embodiment described above, in the one surface 12a of the base layer 12 that faces the emitter layer 14, the emitter-layer facing portion and the region located between the emitter-layer facing portion and the base-electrode facing portion are covered with the surface recombination prevention layer 13. Therefore, effects similar to those of the first embodiment can be obtained.

In the present embodiment, the etching stopper layer 40 is disposed between the base layer 12 and the emitter layer 14. The etching stopper layer 40 is utilized when forming the mesa structure by dry-etching the constituent films forming the emitter layer 14 and the emitter contact layer 15. Before the emitter layer 14 and the emitter contact layer 15 are formed into the mesa structure, the etching stopper layer 40 is also disposed on the second surface recombination prevention layer 13b. Therefore, when forming the emitter layer 14 and the emitter contact layer 15 into the mesa structure, the etching stopper layer 40 makes it easier to identify an etching endpoint. Therefore, when forming the emitter layer 14 and the emitter contact layer 15 into the mesa structure, it is possible to suppress complete removal of the second surface recombination prevention layer 13b, and to prevent the absence of the surface recombination prevention layer 13 in the region of the one surface 12a of the base layer 12 that is capable of serving as the current path.

### Third Embodiment

The following describes a third embodiment of the present disclosure. The present embodiment is an application of the semiconductor device of the first embodiment to a phototransistor (that is, a photoresponsive device) that conducts current utilizing the photoelectric effect. The other configurations of the present embodiment are similar to those of the first embodiment, and therefore a description similar configurations is omitted.

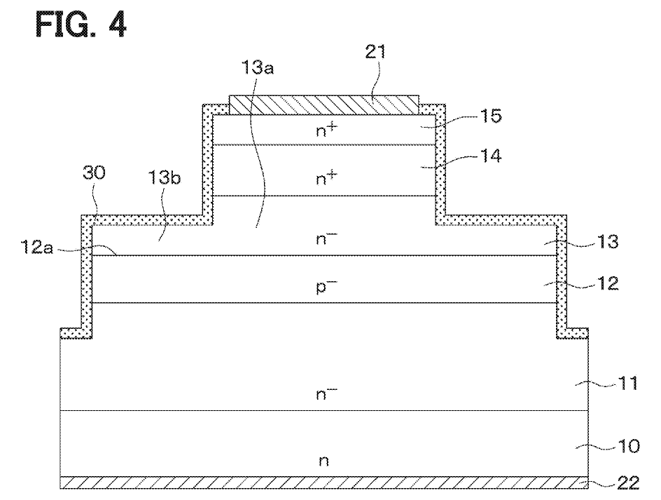

In the semiconductor device of the present embodiment, as shown in FIG. 4, no base electrode 23 is disposed on the base layer 12, and neither the first base contact layer 121 nor the second base contact layer 131 is formed. However, in a cross-section different from that shown in FIG. 4, a potential maintenance electrode for maintaining the potential of the base layer 12 is provided.

The surface recombination prevention layer 13 is disposed so as to cover at least a region of the one surface 12a of the base layer 12 capable of serving as a current path. That is, the surface recombination prevention layer 13 is disposed so as to cover an emitter-layer facing portion of the one surface 12a that faces the emitter layer 14, as well as a surrounding region of the emitter-layer facing portion where current can spread. The region where the current can spread depends on factors such as the carrier concentration and the thickness of the base layer 12, and is determined through simulation or experimentation. In the present embodiment, the surface recombination prevention layer 13 is disposed so as to cover the entire area of the one surface 12a of the base layer 12.

In the present embodiment, the emitter electrode 21 is formed, for example, using a transparent electrode, such as indium tin oxide (ITO). The base layer 12 and the surface recombination prevention layer 13 have the same structures as those in the first embodiment described above.

The configuration of the semiconductor device according to the present embodiment has been described above. In the semiconductor device having the above configuration, when light is incident, the light is absorbed in the base layer 12, generating a base current. This results in a forward bias condition between the emitter layer 14 and the base layer 12, causing electrons to flow from the emitter layer 14 through the base layer 12 to the collector layer 11, thereby turning the semiconductor device on.

In the present embodiment, the surface recombination prevention layer 13 is disposed so as to cover the path on the one surface 12a of the base layer 12 through which current can flow. Therefore, it becomes more difficult for electrons to undergo surface recombination on the one surface 12a of the base layer 12, thereby suppressing the decrease in current gain due to electron loss.

According to the present embodiment described above, the portion on the one surface 12a of the base layer 12 facing the emitter layer 14 that can serve as the current path is covered by the surface recombination prevention layer 13. As a result, surface recombination on the one surface 12a of the base layer 12 facing the emitter layer 14 can be suppressed, thereby suppressing the decrease in current gain. In addition, the surface recombination prevention layer 13 has a configuration different from that of the emitter layer 14. Accordingly, the emitter layer 14 and the surface recombination prevention layer 13 can be designed independently, thereby preventing the manufacturing process from becoming complicated.

In the present embodiment, the second surface recombination prevention layer 13b has a larger band gap than the base layer 12. Therefore, as in the first embodiment described above, when the semiconductor device is in the ON state, it is possible to suppress electrons that have flowed from the emitter layer 14 to the base layer 12 from flowing back into the second surface recombination prevention layer 13b. Accordingly, it is possible to further suppress the decrease in current gain.

In the present embodiment, the second surface recombination prevention layer 13b is configured to be fully depleted when the semiconductor device is in the ON state. Therefore, as in the first embodiment described above, electrons that have flowed from the emitter layer 14 to the surface recombination prevention layer 13 are suppressed from flowing from the first surface recombination prevention layer 13a to the second surface recombination prevention layer 13b, and from being discharged through the second base contact layer 131. Accordingly, it is possible to further suppress the decrease in current gain.

In the present embodiment, the base layer 12 has a peak p-type carrier concentration of 2×10¹⁹ cm⁻³ or less. Therefore, similarly to the first embodiment, it is possible to suppress the shortening of the lifetime of electrons supplied from the emitter layer 14 when the semiconductor device is in the ON state. Accordingly, it is possible to further suppress the decrease in current gain.

### Other Embodiments

Although the present disclosure has been described in accordance with the embodiments, it is understood that the present disclosure is not limited to such embodiments or structures. The present disclosure encompasses various modifications and variations within the scope of equivalents. In addition, while the various combinations and configurations described above are preferred, other combinations and configurations, including more, fewer, or only a single element, are also within the spirit and scope of the present disclosure.

For example, in each of the above-described embodiments, the semiconductor device in which an NPN-type transistor is formed has been described as an example. However, the semiconductor device may alternatively be configured with a PNP-type transistor formed therein. It should be noted that, in the case of a PNP-type transistor, a p-type corresponds to the first conductivity type, and an n-type corresponds to the second conductivity type.

In addition, in each of the above-described embodiments, an example in which the surface recombination prevention layer 13 is n⁻-type has been described. However, the surface recombination prevention layer 13 may also be p-type.

In addition, in each of the above-described embodiments, an example in which the base layer 12 is composed of GaN and the emitter layer 14 is composed of AlGaN has been described. However, the materials constituting the base layer 12 and the emitter layer 14 can be appropriately changed, and, for example, at least one of the base layer 12 and the emitter layer 14 may be composed of a nitride, oxide, carbide, or the like. In this case, the nitride is composed to include at least one selected from a group consisting of aluminum (Al), indium (In), gallium (Ga), and boron (B), and, for example, may be composed to include AlₓGa_{y}N_{1-x-y} (0≤x≤1, 0≤y≤1, x+y=1). The oxide is composed to include at least one selected from a group consisting of aluminum (Al), indium (In), gallium (Ga), boron (B), nickel (Ni), zinc (Zn), magnesium (Mg), germanium (Ge), silicon (Si), titanium (Ti), and Sn (tin), and, for example, may be composed to include (AlₓGa_{y})₂O₃ (0≤x≤1, 0≤y≤1, x+y=1). The carbide is composed to include silicon carbide (SiC) or diamond.

Furthermore, in each of the above-described embodiments, the base layer 12 may be configured by stacking a plurality of layers. In this case, it is preferable that a portion of the base layer 12 located close to the emitter layer 14 has a higher p-type carrier concentration than a portion of the base layer 12 located close to the collector layer 11.

Also, in each of the above-described embodiments, the semiconductor device may have a configuration in which the emitter contact layer 15 is not provided and the emitter layer 14 is connected to the emitter electrode 21.

Furthermore, in each of the above-described embodiments, the support substrate 10 may be an insulating substrate. In this case, for example, a portion of the collector layer 11 that is exposed from the base layer 12 is provided on a side opposite to the support substrate 10, and the collector electrode 22 is electrically connected to the portion of the collector layer 11 that is exposed from the base layer 12.

Furthermore, in each of the above embodiments, the protective film 30 may be omitted.

The above-described embodiments can also be combined with each other. For example, the second embodiment may be combined with the third embodiment, and the etching stopper layer 40 may be disposed.

What is claimed is:

1. A semiconductor device comprising:
a collector layer of a first conductivity type;
a base layer of a second conductivity type disposed above the collector layer;
an emitter layer of the first conductivity type disposed above the base layer, and having a mesa structure such that, in a direction intersecting a stacking direction of the collector layer and the base layer, a width of the emitter layer is narrower than a width of the base layer;
a collector electrode electrically connected to the collector layer;
an emitter electrode electrically connected to the emitter layer;
a base electrode electrically connected to the base layer; and
a surface recombination prevention layer disposed between the emitter layer and the base layer, and having a structure different from the base layer and the emitter layer, wherein
the base layer has one surface that faces the emitter layer,
the one surface has an emitter-layer facing portion that faces the emitter layer in the stacking direction, a base-electrode facing portion that faces the base electrode in the stacking direction, and a region located between the emitter-layer facing portion and the base-electrode facing portion, and
the surface recombination prevention layer is disposed to cover the region of the one surface.

2. The semiconductor device according to claim 1, further comprising:
a first base contact layer of the second conductivity type disposed in the base layer; and
a second base contact layer of the second conductivity type electrically connected to the first base contact layer and disposed in the surface recombination prevention layer, wherein
the base electrode is electrically connected to the base layer via the first base contact layer and the second base contact layer, and
the region of the one surface covered with the surface recombination prevention layer is located between the emitter-layer facing portion and the first base contact layer.

3. The semiconductor device according to claim 2, wherein
the surface recombination prevention layer includes:
a first surface recombination prevention layer disposed between the emitter layer and the base layer; and
a second surface recombination prevention layer disposed between the first surface recombination prevention layer and the second base contact layer, and
the second surface recombination prevention layer has a larger band gap than the base layer.

4. The semiconductor device according to claim 2, wherein
the surface recombination prevention layer includes:
a first surface recombination prevention layer disposed between the emitter layer and the base layer; and
a second surface recombination prevention layer disposed between the first surface recombination prevention layer and the second base contact layer, and
the second surface recombination prevention layer has a carrier concentration and a thickness such that the second surface recombination prevention layer becomes fully depleted when the semiconductor device is in an ON state in which current flows between the emitter layer and the collector layer.

5. The semiconductor device according to claim 2, wherein
each of the first base contact layer and the second base contact layer has a higher carrier concentration than the base layer.

6. The semiconductor device according to claim 5, wherein
the second base contact layer has a higher carrier concentration than the first base contact layer.

7. The semiconductor device according to claim 2, wherein
the base layer has a peak concentration of the second conductivity type of 2×10¹⁹ cm⁻³ 7or less.

8. The semiconductor device according to claim 2, further comprising
an etching stopper layer disposed between the emitter layer and the base layer, wherein
the etching stopper layer is composed of a material that is different from a material of the surface recombination prevention layer and has a lower etching rate than the surface recombination prevention layer.

9. A semiconductor device comprising:
a collector layer of a first conductivity type;
a base layer of a second conductivity type disposed above the collector layer;
an emitter layer of the first conductivity type disposed above the base layer, and having a mesa structure such that, in a direction intersecting a stacking direction of the collector layer and the base layer, a width of the emitter layer is narrower than a width of the base layer;
a collector electrode electrically connected to the collector layer;
an emitter electrode electrically connected to the emitter layer; and
a surface recombination prevention layer disposed between the emitter layer and the base layer, and having a structure different from the base layer and the emitter layer, wherein
the base layer has one surface that faces the emitter layer,
the one surface has a region capable of serving as a current path, and
the surface recombination prevention layer is disposed so as to cover the region of the one surface.

10. The semiconductor device according to claim 9, wherein
the surface recombination prevention layer includes:
a first surface recombination prevention layer disposed between the emitter layer and the base layer; and
a second surface recombination prevention layer disposed at a position different from the first surface recombination prevention layer and covering the region of the one surface capable of serving as the current path, and
the second surface recombination prevention layer has a larger band gap than the base layer.

11. The semiconductor device according to claim 9, wherein
the surface recombination prevention layer includes:
a first surface recombination prevention layer disposed between the emitter layer and the base layer; and
a second surface recombination prevention layer disposed at a position different from the first surface recombination prevention layer and covering the region of the one surface capable of serving as the current path, and
the second surface recombination prevention layer has a carrier concentration and a thickness such that the second surface recombination prevention layer becomes fully depleted when the semiconductor device is in an ON state in which current flows between the emitter layer and the collector layer.

12. The semiconductor device according to claim 9, wherein
the base layer has a peak concentration of the second conductivity type of 2×10¹⁹ cm⁻³12or less.

13. The semiconductor device according to claim 9, further comprising
an etching stopper layer disposed between the emitter layer and the base layer, wherein
the etching stopper layer is composed of a material that is different from a material of the surface recombination prevention layer and has a lower etching rate than the surface recombination prevention layer.

14. The semiconductor device according to claim 1, wherein
at least one of the emitter layer and the base layer is configured to include a nitride, an oxide, or a carbide.

15. The semiconductor device according to claim 14, wherein
when the at least one of the emitter layer and the base layer is configured to include the nitride, the nitride is composed of a material that includes at least one selected from a group consisting of Al, In, Ga, and B, and
when the at least one of the emitter layer and the base layer is configured to include the oxide, the oxide is composed of a material that includes at least one selected from a group consisting of Al, In, Ga, B, Ni, Zn, Mg, Ge, Si, Ti, and Sn.

16. The semiconductor device according to claim 14, wherein
when the at least one of the emitter layer and the base layer is configured to include the nitride, the at least one of the emitter layer and the base layer includes AlₓGa_{y}N_{1-x-y} (0≤x≤1, 0≤y≤1, x+y=1),
when the at least one of the emitter layer and the base layer is configured to include the oxide, the at least one of the emitter layer and the base layer includes (AlₓGa_{y})₂O₃ (0≤x≤1, 0≤y≤ 1, x+y=1), and
when the at least one of the emitter layer and the base layer is configured to include the carbide, the at least one of the emitter layer and the base layer includes SiC or diamond.
